(19) United States
(12) Patent Application Publication
(10) Pub. No.: US 2021/0043431 A1
(43) Pub. Date: Feb. 11, 2021

(54) PLASMA ETCHING METHOD AND PLASMA ETCHING DEVICE

(71) Applicant: TOKYO ELECTRON LIMITED, Tokyo (JP)

(72) Inventors: Mohd Fairuz BIN BUDIMAN, Miyagi (JP); Hiroshi TSUJIMOTO, Miyagi (JP)

(73) Assignee: TOKYO ELECTRON LIMITED, Tokyo (JP)

(21) Appl. No.: 16/979,799

(22) PCT Filed: Jun. 24, 2019
(86) PCT No.: PCT/JP2019/024886

§ 371 Date: Sep. 10, 2020

(30) Foreign Application Priority Data
Jul. 4, 2018 (JP) 2018-127811

(51) Int. Cl. H01J 37/32; H01L 21/67; H01L 21/687; H01L 21/3065; H01L 21/66

(52) U.S. Cl. CPC H01J 37/32642; H01J 37/32449; H01L 21/67248; H01L 21/67069; H01L 21/68735; H01J 2237/334; H01L 21/3065; H01L 22/26; H01J 37/32715; H01J 2237/2007; H01L 21/67103

(57) ABSTRACT

In a plasma etching method for etching a target object by plasma in a state where a pressure in a processing container having a consumable member is maintained at a constant level, variation of time for temperature decrease of the consumable member from a first temperature to a second temperature lower than the first temperature or variation of speed of the temperature decrease of the consumable member from the first temperature to the second temperature is measured. Further, a degree of consumption of the consumable member is estimated from the variation of time or the variation of speed based on information on correlation between the variation of time or the variation of speed and the degree of consumption of the consumable member.

### TECHNICAL FIELD

The present disclosure relates to a plasma etching method and a plasma etching device.

### BACKGROUND

An edge ring is disposed at a periphery of a wafer on a substrate support in a processing chamber of a plasma etching device, and converges plasma toward a surface of the wafer W. During plasma processing, the edge ring is exposed to the plasma and is consumed.

Accordingly, a sheath has a stepped portion at the edge of the wafer, ions are irradiated at an oblique angle, and tilting of an etching shape occurs. Further, an etching rate varies at the edge of the wafer, and an in-plane etching rate of the wafer W becomes non-uniform. Therefore, it is required to replace an edge ring that is consumed more than a predetermined amount with a new one. The replacement time is considered as one of the factors that deteriorate productivity.

Patent Document 1 discloses, e.g., a technique for controlling in-plane distribution of an etching rate by applying a DC voltage from a DC power supply to an edge ring. Patent Document 2 discloses a technique for measuring a degree of consumption of an edge ring from a temporal change of a temperature of the edge ring. Patent Document 3 discloses a technique for measuring a thickness of an edge ring to control a DC voltage to be applied to the edge ring based on the measurement result.

Patent Document 1: Japanese Patent No. 5281309

Patent Document 2: Japanese Patent No. 6027492

Patent Document 3: Japanese Patent Application Publication No. 2005-203489

In accordance with one aspect of the present disclosure, it is suggested to improve productivity of a plasma etching device.

### SUMMARY

In accordance with one aspect of the present disclosure, there is provided a plasma etching method for etching a target object by plasma in a state where a pressure in a processing container having a consumable member is maintained at a constant level, the plasma etching method comprising: measuring variation of time temperature decrease of the consumable member from a first temperature to a second temperature lower than the first temperature or is variation of speed of the temperature decrease of the consumable member from the first temperature to the second temperature; and estimating a degree of consumption of the consumable member from the variation of time or the variation of speed based on information on correlation between the variation of time or the variation of speed and the degree of consumption of the consumable member.

### EFFECT

In accordance with one aspect of the present disclosure, it is suggested to improve productivity of a plasma etching device.

### BRIEF DESCRIPTION OF THE DRAWINGS

FIG. 1 shows an example of a plasma etching device according to an embodiment.

FIGS. 2A and 2B explain changes in an etching rate and tilting due to consumption of an edge ring.

FIG. 3 shows an example of a cross section of the edge ring and its surrounding structure according to an embodiment.

FIG. 4 is a flowchart showing an example of pre-processing of a DC voltage control process according to an embodiment.

FIG. 5 shows an example of a graph showing a correlation table between a difference in the time taken to decrease a temperature and a consumption amount of an edge ring according to an embodiment.

FIG. 6 shows an example of a graph showing a correlation table between a difference in the time taken to decrease a temperature and an appropriate value of a DC voltage according to an embodiment.

FIG. 7 is a flowchart showing an example of an etching process including the DC voltage control process according to an embodiment.

FIGS. 8A and 8B explain application of a DC voltage in the DC voltage control process according to the embodiment.

FIG. 9 shows an example of an edge ring divided into three parts according to an embodiment.

FIG. 10 shows an example of a system according to an embodiment.

### DETAILED DESCRIPTION

Hereinafter, embodiments of the present disclosure will be described in detail with reference to the accompanying drawings. Like reference numerals will be given to substantially like parts throughout this specification and the drawings, and redundant description. thereof will be omitted.

### Plasma Etching Device

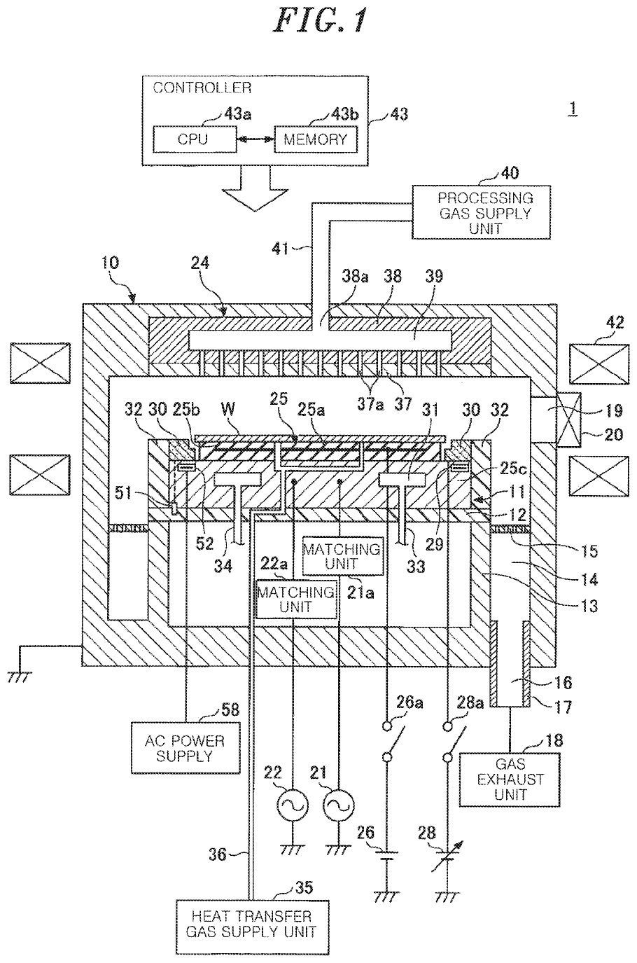

First, an example of a plasma etching device 1 according to an embodiment of the present disclosure will be described with reference to FIG. 1. FIG. 1 shows an example of a cross section of the plasma etching device 1 according to the embodiment. The plasma etching device 1 of the present embodiment is a reactive ion etching (RIE) type plasma etching device.

The plasma etching device 1 includes a cylindrical processing container 10 that can be evacuated. The processing container 10 is made of metal, e.g., aluminum, stainless steel, or the like, and an inner space thereof serves as a processing chamber where plasma processing such as plasma etching, plasma CVD, or the like is performed. The processing container 10 is grounded.

A disc-shaped substrate support 11 is disposed inside the processing container 10. A wafer W is placed on the substrate support 11. The substrate support 11 is supported by a cylindrical supporting member 13 extending vertically upward from a bottom portion of the processing container 10 through a disc-shaped holder 12 made of alumina (Al₂O₃).

The substrate support 11 has an electrostatic chuck 25 and a base 25c. The base 25c is made of aluminum. The electrostatic chuck 25 is disposed on the base 25c. An edge ring (focus ring) 30 is disposed on an upper outer periphery of the base 25c to surround the periphery of the wafer W. The outer circumferences of the base 25c and the edge ring 30 are covered by an insulator ring 32.

The electrostatic chuck 25 has a structure in which an attraction electrode 25a that is a conductive film is embedded in a dielectric layer 25b. A DC power supply 26 is connected to the attraction electrode 25a through a switch 26a. The electrostatic chuck 25 generates an electrostatic force such as Coulomb force or the like by a DC voltage applied from the DC power supply 26 to the attraction electrode 25a, and attracts and holds the wafer W by the electrostatic force thus generated.

The edge ring 30 is made of silicon or quartz. A heater 52 is embedded in the base 25c near the bottom surface of the edge ring 30. An AC power supply 58 is connected to the heater 52. When a power from the AC power supply 58 is applied to the heater 52, the heater 52 is heated and, thus, the edge ring 30 is set to a predetermined temperature such as 90° C. or the like. A temperature of a bottom surface of the edge ring 30 can be measured by a radiation thermometer 51.

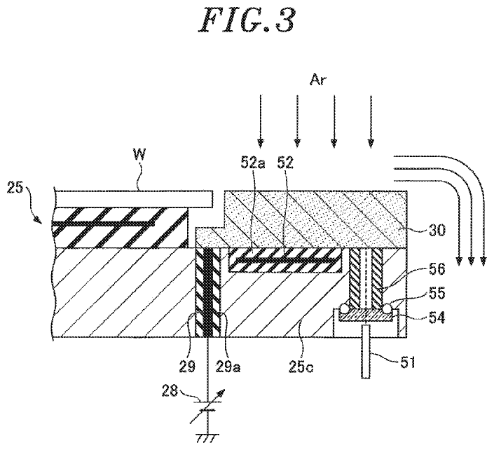

A variable DC power supply 28 is connected to the electrode 29 through a switch 28a, and outputs a DC voltage from the electrode 29 to the edge ring 30 in contact with the electrode 29 (see FIG. 3). In the present embodiment, a thickness of a sheath above the edge ring 30 is controlled in response to the consumption amount of the edge ring 30 by controlling the DC voltage applied from the variable DC power supply 28 to the edge ring 30 to an appropriate value. Accordingly, the occurrence of tilting is suppressed, and the in-plane distribution of the etching rate is controlled. The variable DC power supply 28 is an example of a DC power supply for supplying a DC voltage to be applied to the edge ring 30.

A first HF power supply 21 is connected to the substrate support 11 through a matching unit 21a. The first RF power supply 21 applies an RF power (HF power) having a frequency for plasma generation and RIE (e.g., a frequency of 13 MHz) to the substrate support 11. A second RF power supply 22 is connected to the substrate support 11 through a matching unit 22a. The second RF power supply 22 applies an RF power (LF power) having a frequency for bias application (e.g., a frequency of 3 MHz) lower than the frequency for plasma generation and RIE to the substrate support 11. In this manner, the substrate support 11 also functions as a lower electrode. The HF power may be applied to a gas shower head 24.

An annular coolant space 31 extending in, e.g., a circumferential direction, is formed inside the base 25c. A coolant, e.g., cooling water, having a predetermined temperature, is supplied from a chiller unit and circulated in the coolant space 31 through lines 33 and 34. Accordingly, the electrostatic chuck 25 is cooled.

A heat transfer gas supply unit 35 is connected to the electrostatic chuck 25 through a gas supply line 36. The heat transfer gas supply unit 35 supplies a heat transfer gas to the space between the upper surface of the electrostatic chuck 25 and the backside of the wafer W through the gas supply line 36. As the heat transfer gas, a thermally conductive gas, e.g., He gas or the like, is preferably used.

A gas exhaust passage 14 is formed between the inner surface of the processing container 10 and the outer peripheral surface of the cylindrical supporting member 13. An annular baffle plate 15 is disposed in the gas exhaust passage 14, and a gas exhaust port 16 is disposed at a bottom portion. A gas exhaust unit 18 is connected to the gas exhaust port 16 through a gas exhaust line 17. The gas exhaust unit 18 includes a vacuum pump, and decreases a pressure in a processing space inside the processing container 10 to a predetermined vacuum level. Further an automatic pressure control valve (hereinafter referred to as “APC”) that is a variable butterfly valve is disposed in the gas exhaust line 17. The APC automatically controls a pressure in the processing container 10. A gate valve 20 for opening/closing a loading/unloading port 19 for the wafer W is provided at the sidewall of the processing container 10.

A gas shower head 24 is disposed at a ceiling portion of the processing container 10. The gas shower head 24 includes an electrode plate 37 and an electrode holder 38 for detachably holding the electrode plate 37. The electrode plate 37 has a plurality of gas injection holes 37a. The gas shower head 24 also functions as an upper electrode while facing the substrate support 11.

A buffer space 39 formed in the electrode holder 38. A processing gas supply unit 40 is connected to a gas inlet port 38a of the buffer space 39 through a gas supply pipe 41. The processing gas supply unit 40 supplies a processing gas into the buffer chamber 39 and the processing gas is supplied to the processing space between the gas shower head 24 and the substrate support 11 through the gas injection holes 37a. A magnet 42 extending annularly or concentrically is disposed around the processing container 10. The processing gas supply unit 40 is an example of a gas supply unit for supplying a gas.

The respective components of the plasma etching device 1 are connected to and controlled by a controller 43. The respective components may include, e.g., the gas exhaust unit 18, the matching units 21a and 22a, the first RF power supply 21, the second RF power supply 22, the switches 26a and 28a, the DC power supply 26, the variable DC power supply 28, the heat transfer gas supply unit 35, the processing gas supply unit 40, and the like.

The controller 43 is a computer including a central processing unit (CPU) 43a and a memory 43b. The CPU 43a reads out and executes a control program and a processing recipe of the plasma etching device 1 stored in the memory 43b to control the plasma etching process performed by the plasma etching device 1.

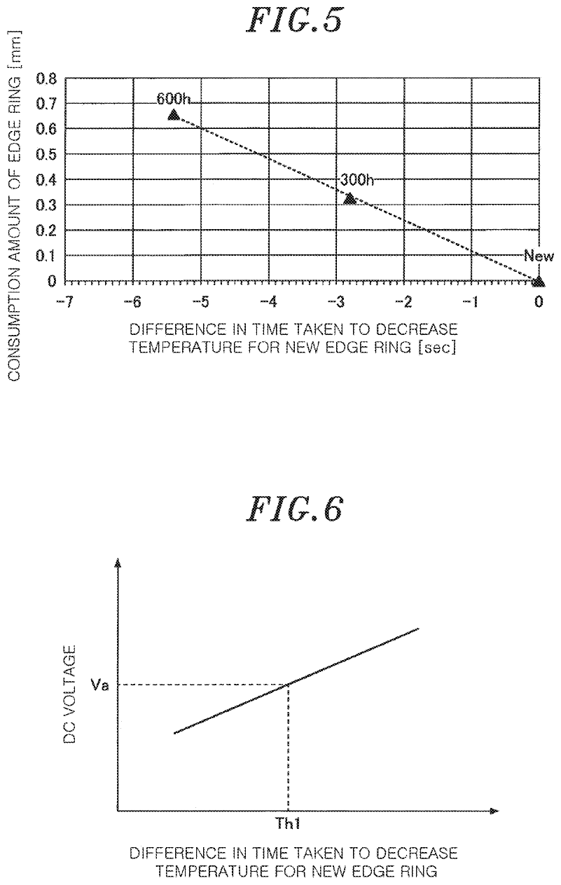

The controller 43 also stores in the memory 43b various correlation information (e.g., correlation tables: see FIGS. 5 and 6) obtained in the pre-processing of the DC voltage control process of the edge ring 30 which will be described later. The memory 43b is an example of a storage unit that stores the correlation information represented by a correlation table or an equation.

The plasma etching device 1 performs plasma etching on the wafer W. In the case of performing plasma etching, first, the gate valve 20 is opened and, then, the wafer W is loaded into the processing container 10 and placed on the electrostatic chuck 25. A DC voltage is applied from the DC power supply 26 to the attraction electrode 25a, and the wafer W is attracted to and held on the electrostatic chuck 25.

The heat transfer gas is supplied to the gap between the upper surface of the electrostatic chuck 25 and the backside of the wafer W. The processing gas from the processing gas supply unit 40 is introduced into the processing container 10, and a pressure in the processing container 10 is reduced by the gas exhaust unit 18 or the like. The first RF power supply 21 and the second RF power supply 22 supply the first RF power and the second RF power to the substrate support 11, respectively.

In the processing container 10 of the plasma etching device 1, a horizontal magnetic field is generated in one direction by the magnet 42, and a vertical RF electric field is generated by the RF power applied to the substrate support 11. Accordingly, the processing gas introduced from the gas shower head 24 is turned into plasma, and the wafer W is subjected to predetermined etching by radicals and ions in the plasma.

The heater 52 is an example of a heating unit for heating a consumable member such as the edge ring 30 or the like. The heating unit is not limited thereto, and may be, e.g., a heat medium or the like. The radiation thermometer is an example of a measuring unit for measuring a temperature of the consumable member. The measuring unit is not limited to a specific thermometer, and may be an optical thermometer such as Luxtron or the like, a thermocouple, or the like.

### Consumption of Edge Ring

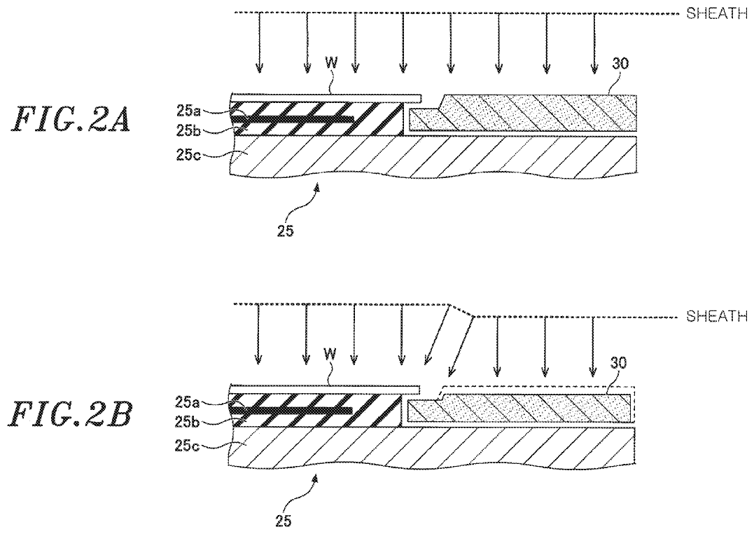

Next, the change in the sheath due to the consumption of the edge ring 30, the variation in the etching rate, and the occurrence of tilting will be described with reference to FIGS. 2A and 2R. As shown in FIG. 2A, a thickness of a new edge ring 30 is designed such that the upper surface of the wafer W and the upper surface of the edge ring 30 are located at the same height. At this time, a height of a sheath above the wafer W is the same as a height of a sheath above the edge ring 30 during the plasma processing. In this state, ions from the plasma are irradiated onto the wafer W and the edge ring 30 substantially vertically. Accordingly, an etching shape such as a hole formed on the wafer W or the like is vertical at both of the central portion and the edge portion of the wafer W, and there is no tilting in which the etching shape is inclined. Further, the in-plane etching rate of the wafer W is controlled to be uniform.

However, the edge ring 30 is exposed to the plasma and is consumed during the plasma processing. Then, as shown in FIG. 2B, the thickness of the edge ring 30 becomes thin, and the upper surface of the edge ring 30 becomes lower than the upper surface of the wafer W. Accordingly, the height of the sheath above the edge ring 30 becomes lower than the height of the sheath above the wafer W.

When there is a step difference in the height of the sheath, the ions are irradiated obliquely and the tilting in which the etching shape is inclined may occur at the edge of the wafer W. Alternatively, the etching rate at the edge portion of the wafer W may vary, and the in-plane etching rate of the wafer W may become non-uniform. Hereinafter, an angle at which the etching shape is tilted from a vertical direction due to the oblique ion irradiation is referred to as “tilt angle.”

However, it possible to control the etching shape to be substantially vertical and realize the uniformity of the in-plane distribution of the etching rate by applying an appropriate DC voltage from the variable DC power supply 28 to the edge ring 30 in response to the consumption amount of the edge ring 30. However, the edge ring 30 is exposed to the plasma and is gradually consumed during the plasma processing. Therefore, the appropriate value of the DC voltage applied from the variable DC power supply 28 varies depending on the consumption amount of the edge ring 30. As shown in FIG. 2B, the consumption of the edge ring 30 includes not only abrasion of the edge ring 30 in a thickness direction, but also reduction in a width, deterioration of a material, or the like. Accordingly, when the consumption amount of the edge ring 30 is estimated only by measuring the thickness of the edge ring 30 and the DC voltage applied to the edge ring 30 is calculated based on the estimated consumption amount, the estimated value of the consumption amount of the edge ring 30 may be different from the actual consumption amount, which makes it difficult to apply an appropriate DC voltage to the edge ring 30.

Therefore, in the present embodiment, the consumption amount of the edge ring is calculated from a heat capacity, and an appropriate value of the DC voltage applied to the edge ring 30 is obtained based on the calculated heat capacity. Specifically, in the present embodiment, the time taken to decrease the temperature of the edge ring 30 is measured as the heat capacity; the consumption amount of the edge ring 30 is predicted based on the time taken to decrease the temperature; and the appropriate value of the DC voltage applied to the edge ring 30 is obtained and applied to the edge ring 30. The heat capacity includes not only the heat capacity of the edge ring 30 but also the heat capacity of surrounding members of the edge ring 30. In other words, the time taken to decrease the temperature of the edge ring 30 corresponds to the heat capacity including not only the heat capacity of the edge ring 30 but also the heat capacity of the surrounding members of the edge ring 30.

### Edge Ring and its Surrounding Structure

In the present embodiment, the consumption amount of the edge ring 30 is calculated from the heat capacity by estimating the consumption amount of the edge ring 30 from the measured time taken to decrease the temperature of the edge ring 30. Therefore, it is possible to control an appropriate DC voltage to be applied to the edge ring 30. The surrounding structure of the edge ring 30 for measuring the temperature of the edge ring 30 will be described with reference to FIG. 3. FIG. 3 shows an example of a cross section of the edge ring 30 and its surrounding structure according to an embodiment.

The edge ring 30 has a ring shape and is disposed on the upper outer peripheral surface of the base 25c to surround the wafer W. An insulator 52a is disposed on the upper surface of the base 25c to be in contact with the bottom surface of the edge ring 30, and a heater 52 is embedded in the insulator 52a. When the power from the AC power supply 58 is applied to the heater 52, the heater 52 is heated and the temperature of the edge ring 30 is increased.

The radiation thermometer 51 measures a temperature of the bottom surface of the edge ring 30. The tip end of the radiation thermometer 51 is close to glass 54 that is made of Ge or the like and has been subjected to antireflection treatment. Infrared light or visible light is emitted from the tip end of the radiation thermometer 51. The emitted infrared light or visible light reaches the bottom surface of the edge ring 30 through the cavity in the insulator 56 and then is reflected. In the present embodiment, the temperature of the edge ring 30 is measured by measuring the intensity of the reflected infrared light or visible light. The O-ring 55 seals a vacuum space in the processing container 10 from an atmospheric space in the insulator 56. The variable DC power supply 28 connected to the electrode 29 disposed in the insulator 29a. A DC voltage corresponding to the consumption amount of the edge ring 30 is applied to the electrode 29 from the variable DC power supply 28.

In the present embodiment, the temperature of the edge ring 30 is set to 90° C. using the heater 52, and then is decreased to 20° C. At that time, the time taken to decrease the temperature of the edge ring 30 from 90° C. to 20° C. is measured while supplying Ar gas at a flow rate of 60 sccm into the processing container 10 and maintaining a pressure in the processing container 10 at 100 mT. A purge gas supplied in this step is not limited to Ar gas, but is preferably an inert gas. Further, the RF powers outputted from the first RF power supply 21 and the second RF power supply 22 are set to 0 W.

The controller 43 calculates the consumption amount of the edge ring 30 based on the measured time taken to decrease the temperature, and calculates an appropriate value of the DC voltage corresponding to the consumption amount of the edge ring 30. The controller 43 controls the calculated appropriate value of the DC voltage to be applied to the electrode 29.

### Pre-Processing of DC Voltage Control Process

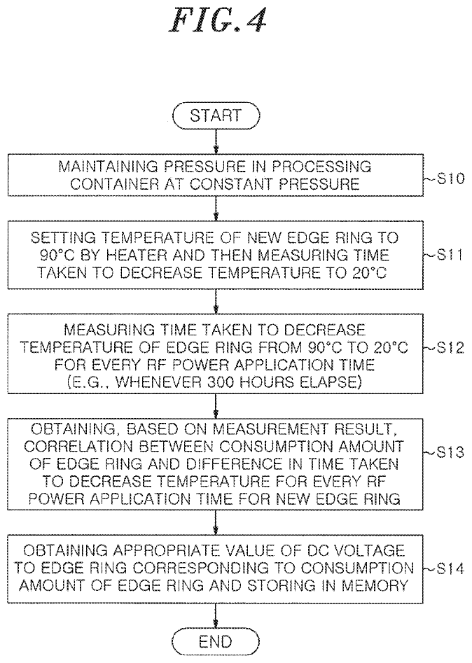

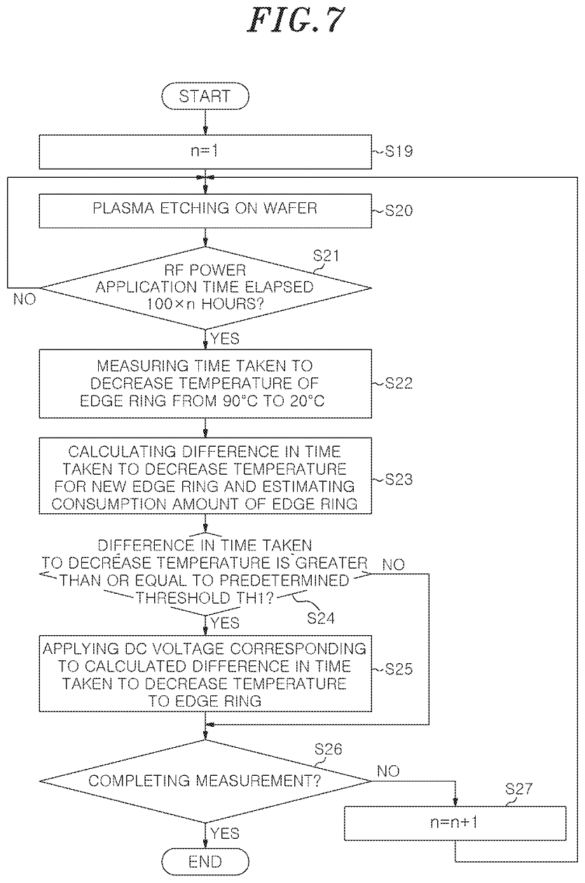

Next, the pre-processing for collecting information on correlation between the time taken to decrease the temperature and the consumption amount of the edge ring to calculate the consumption amount of the edge ring 30 based on the measured time taken to decrease the temperature will be described with reference to FIG. 4. FIG. 4 is a flowchart showing an example of the pre-processing of the DC voltage control process (see FIG. 7) of applying an appropriate value of the DC voltage to the edge ring 30 according to an embodiment.

When the pre-processing is started, the controller 43 maintains a pressure in the processing container 10 at a constant pressure of 100 mT while supplying Ar gas at a flow rate of 60 sccm into the processing container 10 (step S10).

Next, the controller 43 inputs heat into a new edge ring 30 while maintaining the power applied from the AC power source 58 to the heater 52 at a constant level. The controller 43 sets the temperature of the bottom surface of the edge ring 30 measured by the radiation thermometer 51 to 90° C. (step S11). Next, the controller 43 measures the time taken to decrease the temperature of the bottom surface of the edge ring 30 from 90° C. to 20° C. due to heat removal by Ar gas (step S11).

Next, the controller 43 measures the time taken to decrease the temperature of the bottom surface of the edge ring 30 from 90° C. to 20° C. for every RF power application time (e.g., whenever 300 hours elapse) (step S12). The RF power application time is an example of the usage time of the edge ring 30.

Next, the controller 43 obtains, based on the measurement result of the time taken to decrease the temperature for every RF power application time, information (correlation information) on correlation between the consumption amount of the edge ring 30 and a difference (variation value) in the time taken to decrease the temperature for every RF power application time (e.g., every 300 h) with respect to the time taken to decrease the temperature of the new edge ring 30 (step S13).

Next, the controller 43 obtains an appropriate value of the DC voltage to be applied to the edge ring 30 corresponding to the consumption amount of the edge ring 30, stores the information obtained in the pre-processing in the memory 43b (step S14), and completes this processing.

FIG. 5 shows an example of the correlation information between the difference in the time taken to decrease the temperature obtained as result of step S13 and the consumption amount of the edge ring 30. In FIG. 5, the horizontal axis represents the difference in the time taken to decrease the temperature with respect to the new edge ring 30, and the vertical axis represents the consumption amount of the edge ring 30.

In the example of FIG. 5, the time taken to decrease the temperature of the bottom surface of the new edge ring 30 from 90° C. to 20° C. was used as a reference. The time taken to decrease the temperature of the bottom surface of the edge ring 30 from 90° C. to 20° C. was measured five times for each RF power application time of 0 h (new edge ring), 300h, and 600h. Then, each of the average values of the five measured values was used to calculate the difference between the average value of the time taken to decrease the temperature of the bottom surface of the new edge ring 30 and each of the average values of the time taken to decrease the temperature. Then, correlation information between the differences of the time taken to decrease the temperature (average values) and the consumption amounts of the edge ring 30 at 300h and 600h was obtained to create a correlation table.

Referring to FIG. 5 showing an example of the result, the time taken to decrease the temperature is proportional to the consumption amount of the edge ring 30 at the RF power application time of 0 h (new edge ring 30), 300h and 600h. From this result, it was found that as the usage time of the edge ring 30 increases (the RF power application time increases) and the consumption of the edge ring 30 due to exposure to the plasma increases, the heat capacity of the edge ring 30 decreases and the time taken to decrease the temperature of the edge ring 30 from 90° C. to 20° C. is shortened.

A correlation table indicating correlation between the difference in the time taken to decrease the temperature and an appropriate value of the DC voltage can be created from the proportional relationship between the time taken to decrease the temperature and the consumption amount of the edge ring 30 and the previously obtained information on the correlation between the consumption amount of the edge ring 30 and an appropriate value of the DC voltage applied to the edge ring 30. An example of a graph showing the correlation table is shown in FIG. 6. An appropriate value of the DC voltage applied to the edge ring 30 corresponding to the difference between the measured time taken to decrease the temperature and the time taken to decrease the temperature of the new edge ring 30 can be obtained based on the graph showing the correlation table shown in FIG. 6.

From the above, the DC voltage corresponding to the consumption amount of the edge ring 30 can be calculated by obtaining an appropriate value of the DC voltage corresponding to the measured time taken to decrease the temperature based on the graph showing the correlation table of FIG. 6. Accordingly, it is possible to control an appropriate value of the DC voltage corresponding to the consumption amount of the edge ring 30 to be applied to the edge ring 30 (the DC voltage control process).

For the consumption amount of the edge ring 30 measured for every RF power application time, the consumption amount of the edge ring 30 (the reduced thickness of the edge ring 30) may be actually measured for every RF power application time. Further, the consumption amount of the edge ring 30 may be estimated from the RF power application time. In addition, the consumption amount of the edge ring 30 may be calculated from the tilt angle of the etching shape formed at the edge portion of the wafer W for every RF power application time. The pressure, the temperature, and the RF power application time shown in FIG. 4 are examples and are not limited thereto.

### Etching Process Including DC Voltage Control Process

Hereinafter, the etching process including the DC voltage control process according to an embodiment will be described with reference to FIG. 7. FIG. 7 is a flowchart showing an example of the etching process including the DC voltage control process according to the embodiment.

In this process, first, the controller 43 sets 1 to a variable n (step S19) and performs plasma etching on a wafer (step S20). Next, it is determined whether the RF power application time has elapsed 100×n hours (step S21). When the RF power application time has elapsed 100×n hours, the controller 43 measures the time taken to decrease the temperature of the edge ring 30 from 90° C. to 20° C. (step S22). The unit of the elapsed time in step S21 is not limited to 100×n.

Next, the controller 43 calculates the difference in the time taken to decrease the temperature with respect to the new edge ring 30 and estimates the consumption amount of the edge ring 30 (step S23). For example, the consumption amount of the edge ring 30 can be estimated from the difference in the time taken to decrease the temperature with respect to the new edge ring 30 based on, e.g., the correlation graph shown in FIG. 5. The time taken to decrease the temperature may be a value measured once or an average value of values measured multiple times.

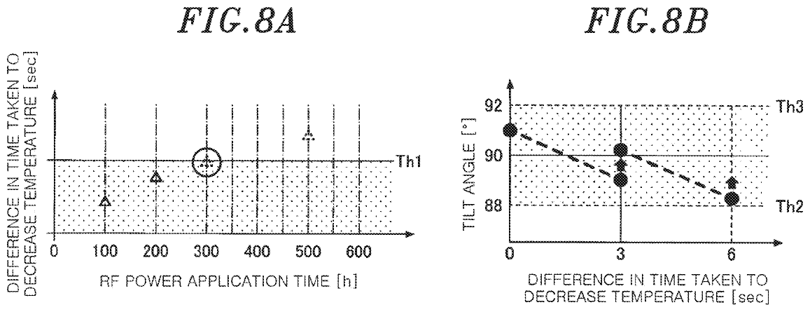

Next, the controller 43 determines whether or not the difference in the time taken to decrease the temperature is greater than or equal to a predetermined threshold Th1 (step S24). As shown in FIG. 8A, for example, as the RF power application time increases, the difference in the time taken to decrease the temperature increases. If the difference in the time taken to decrease the temperature with respect to the new edge ring 30 is greater than or equal to the threshold value Th1, the consumption amount of the edge ring 30 becomes unacceptable. Therefore, when it is determined in step S24 of FIG. 7 that the difference in the time taken to measure the temperature is greater than or equal to the threshold Th1, the controller 43 applies an appropriate value of the DC voltage corresponding to the calculated difference in the time taken to decrease the temperature to the edge ring 30 (step 525), and the processing proceeds to step 26. At this time, the appropriate value of the DC voltage corresponding to the difference in the temperature taken to decrease the temperature is calculated based on the correlation information stored in the memory 43b indicating the correlation between the DC voltage and the time taken to decrease the temperature calculated in the pre-processing of the DC voltage control process. For example, referring to a graph showing the correlation table of FIG. 6, when the difference in the temperature to decrease the temperature with respect to the new edge ring 30 becomes equal to the threshold Th1, a DC voltage is calculated as an appropriate value of the DC voltage applied to the edge ring 30.

By applying the DC voltage calculated as described above to the edge ring 30, the height of the sheath above the edge ring 30 becomes substantially the same as the height of the sheath above the wafer W. Therefore, ions are irradiated substantially vertically. Accordingly, when the difference in the time taken to decrease the temperature in FIG. 8B is 3 sec, for example, the tilt angle at the edge portion of the wafer W is corrected and the tilt angle becomes close to 90°. Hence, the tilt angle can be controlled within a range of Th2 to Th1 indicating the allowable range of the tilt angle even at the edge portion of the wafer W by applying an appropriate value of the DC voltage corresponding to the consumption amount of the edge ring 30 to the edge ring 30.

Referring back to FIG. 7, when it is determined in step S24 that the difference in the time taken to decrease the temperature is smaller than the threshold Th1, the controller 43 determines that it is unnecessary to correct the tilt angle by applying the DC voltage to the edge ring 30 or changing the DC voltage app tied to the edge ring 30, and the processing immediately proceeds to step S26.

In step S26, the controller 43 determines whether or not to complete the measurement. When it is determined that the measurement is to be completed, the processing is ended. When it is determined that the measurement is not completed, 1 is added to the variable n (step S27), and the processing returns to step S20 to repeat the subsequent steps of step S20.

In the plasma etching method including the DC voltage control process of steps S21 to S26, the application of the DC voltage to the edge ring 30 is controlled while the plasma etching is being performed on the wafer W.

In accordance with the DC voltage control process of the present embodiment, the time taken to decrease the temperature of the edge ring 30 is measured, and the appropriate value of the DC voltage corresponding to the measured time taken to decrease the temperature calculated. Thus, the DC voltage corresponding to the consumption amount of the edge ring 30 is calculated. Then, by applying the calculated appropriate value of the DC voltage to the edge ring 30, the sheath above the edge ring 30 and the sheath above the wafer W can be aligned at the same height. Accordingly, at least one of the occurrence of tilting and the variation in the etching rate can be suppressed. For example, when the calculated appropriate value of the DC voltage is 100V, the DC voltage of 100V is applied to the edge ring 30 to correct the tilting angle and the etching rate of the consumed edge ring 30 to those of the new edge ring 30.

Therefore, even if the edge ring 30 is consumed, the replacement timing of the edge ring 30 can be delayed by controlling the DC voltage. The replacement time of the edge ring 30 includes, e.g., the time to open the processing container 10 and replace the edge ring 30, and the time to close the processing container 10 after the replacement and adjust the atmosphere in the processing container 10 by performing cleaning or seasoning. Accordingly, the productivity can be improved by delaying the replacement timing of the edge ring 30.

Although the measurement timing of the time taken to decrease the temperature was determined based on the RF power application time in step S21, the present disclosure is not limited thereto. For example, the time taken to decrease the temperature may be measured when is determined that a specific number of wafers W have been processed. The specific number of wafers W may be one, twenty-five (e.g., one lot), or any other number.

Although the time taken to decrease the temperature of the bottom surface of the edge ring 30 from 90° C. to 20° C. was measured in the above description, the measured temperature is not limited thereto. 90° C. is an example of a first temperature, and 20° C. is an example of a second temperature lower than the first temperature. The first temperature and the second temperature are not limited to 90° C. and 20° C., respectively, and two temperatures can be appropriately set as long as the second temperature is lower than the first temperature.

In the above-described embodiments, the time taken to decrease the temperature of the bottom surface of the edge ring 30 from 90° C. to 20° C. was measured in the pre-processing and the DC voltage control processing. On the other hand, a speed of temperature decrease may be measured. Further, in the present embodiment, the temperature of the bottom surface of the edge ring 30 was measured by the radiation thermometer 51. However, the present disclosure is not limited thereto, and any surface of the edge ring 30 may be measured.

Further, in the above-described embodiments, the temperature of the edge ring 30 was decreased to 20° C. by supplying Ar gas at a constant flow rate and removing heat from the surface of the edge ring 30 using the Ar gas. However, the present disclosure is not limited thereto, and the coolant space 31 may be disposed below the edge ring 30 and the temperature of the edge ring 30 may be decreased by circulating brine therethrough.

The pressure in the processing container 10 can be adjusted at a constant level either by supplying Ar gas into the processing container 10 at a constant flow rate or by controlling the exhaust side using an APC or the like, or by performing both of these processes.

Further, in the above-described embodiments, the consumption amount of the edge ring 30 was estimated as an example of a degree consumption of the edge ring. However, it is also possible to calculate a DC voltage from the measured time taken to decrease the temperature or the measured speed of the temperature decrease based on the graph showing the correlation table of FIG. 6, and apply the calculated DC voltage to the edge ring 30. Accordingly, an appropriate value of the DC voltage can be obtained without estimating the consumption amount of the edge ring 30.

The edge ring 30 of the present embodiment is an example of a consumable member. The consumable member may also be the gas shower head 24 (the upper electrode). In this case, the gas shower head 24 provided with a measuring unit for measuring a temperature of the gas shower head 24, a variable DC power supply for applying a DC voltage, and a heating unit.

### Modification

In the above-described embodiments, the DC voltage applied to the edge ring 30 was controlled based on the measured time taken to decrease the temperature or the measured speed of the temperature decrease. On the other hand, in the modification, the driving amount of the edge ring 30 is controlled instead of or in addition to the application of the DC voltage to the edge ring 30.

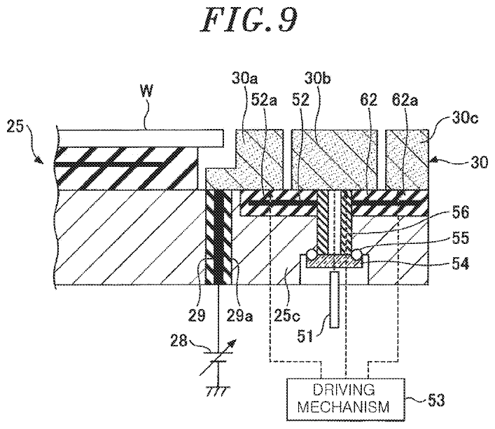

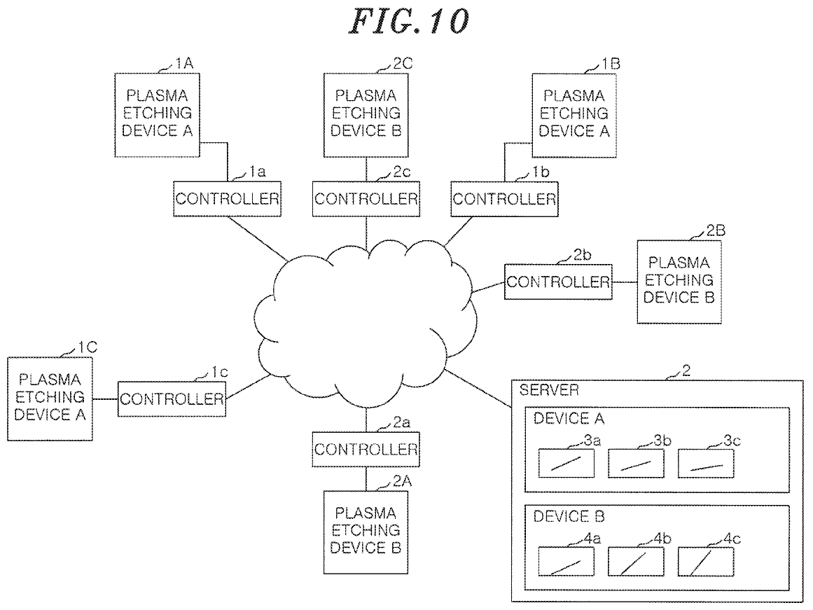

The edge ring 30 and its surrounding structure according to a modification of the embodiment will be described with reference to FIG. 9. FIG. 9 shows an example of a cross section of an edge ring divided into three parts and its surrounding structure according to a modification of the embodiment.

In the modification shown in FIG. 9, the radiation thermometer 51 is disposed to measure the temperature of the central portion of the bottom surface of the edge ring 30. Further, in this modification, the heater 52 embedded in the insulator 52a and a heater 62 embedded in an insulator 62a are disposed on the inner peripheral side and the outer peripheral side of the bottom surface of the edge ring 30, respectively.

With this configuration, the temperature measurement position of the radiation thermometer 51 according to the modification is closer to the heaters 52 and 62 compared to the temperature measurement position of the radiation thermometer 51 of the present embodiment, and the temperature of the central portion on the bottom surface of the edge ring 30 is measured. However, the heaters 52 and 62 and the radiation thermometer 51 may be close to each other or distant from each other. For example, the radiation thermometer 51 is not necessarily disposed at the outer peripheral portion or the central portion of the bottom surface of the edge ring 30, and may be disposed at the inner peripheral portion of the bottom surface of the edge ring 30 to measure the temperature of the inner peripheral portion of the bottom surface of the edge ring 30. Regardless of the position of the radiation thermometer 51, the correlation information on the correlation between the DC voltage and the time taken to decrease the temperature or the speed of the temperature decrease of the edge ring 30 is obtained in the pre-processing and stored in the memory 43b. Therefore, in the case of performing the plasma etching method shown in the flowchart of FIG. 7, an appropriate DC voltage corresponding to the measured time taken to decrease the temperature can be calculated based on the correlation information on the correlation between the time taken to decrease the temperature and the DC voltage, which is stored in the memory 43b, and the calculated appropriate DC voltage can be applied to the edge ring 30.

In this modification, the edge ring 30 is divided into an inner peripheral edge ring 30a, a central edge ring 30b, and an outer peripheral edge ring 30c arranged in that order from an inner peripheral side. Each of the inner peripheral edge ring 30a, the central edge ring 30b, and the outer peripheral edge ring 30c is arranged in ring shape. At least one of the inner peripheral edge ring 30a, the central edge ring 30b, and the outer peripheral edge ring 30c is connected to a driving mechanism 53. The controller 43 controls a driving amount of the driving mechanism 53 in response to the consumption amount of the edge ring 30 estimated in the above-described embodiment or in this modification. Therefore, the control such as the alignment of the height of the sheath above the edge ring 30 and the height of the sheath above the wafer W or the like can be performed by raising at least one of the inner peripheral edge ring 30a, the central edge ring 30b, and the outer peripheral edge ring 30c. Accordingly, at least one of the occurrence of tilting and the variation in the etching rate can be suppressed by controlling the DC voltage applied to the edge ring 30 and controlling the driving amount of the drive mechanism 53. The edge ring 30 is not necessarily divided into three parts, and may be divided into multiple parts so that any one of the multiple parts can be driven.

Hereinafter, an example of control of a server 2 by the controller 43 in a system using information on correlation between the difference in the time taken to decrease the temperature and the DC voltage stored in the memory 43b will be described with reference to FIG. 10. FIG. 10 shows an example of a system according to an embodiment.

In this system, controllers 1a to 1c for controlling a plasma etching device A (hereinafter also referred to as “device A”) and controllers 2a to 2c for controlling a plasma etching device B (hereinafter also referred to as “device B”) are connected to the server 2 through a network.

For example, plasma etching devices 1A, 1B, and 1C may be used as examples of the device A. However, the device A is not limited thereto. The plasma etching devices 1A to 1C are controlled by the controllers 1a to 1c, respectively.

For example, plasma etching devices 2A, 2B, and 2C may be used as examples of the device B. However, the device B is not limited thereto. The plasma etching devices 2A to 2C are controlled by the controllers 2a to 2c, respectively.

The controllers 1a to 1c and the controllers 2a to 2c transmit, to the server 2, the correlation information on the correlation between the difference in the time taken to decrease the temperature and the DC voltage stored in each memory (storage unit). The server 2 receives information 3a, 3b, and 3c on the correlation between the difference in the time taken to decrease the temperature and the DC voltage from the controllers 1a to 1c for controlling the device A (the plasma etching devices 1A to 1C). Further, the server 2 receives information 4a, 4b, and 4c on correlation between the difference in the time taken to decrease the temperature and the DC voltage from the controllers 2a to 2c for controlling the device B (the plasma etching devices 2A to 2C). In FIG. 10, for convenience, the correlation information on the correlation between the difference in the time taken to decrease the temperature and the DC voltage is schematically illustrated as graphs.

The server 2 classifies the information 3a, 3b, 3c, and the like, on the correlation between the difference in the time taken to decrease the temperature and the DC voltage in the device A and the information 4a, 4b, 4c, and the like on the correlation between the difference in the time taken to decrease the temperature and the DC voltage in the device B into different categories.

The server 2 calculates an appropriate value of the DC voltage with respect to the difference in the time taken to decrease the temperature of the device A based on the information 3a, 3b, 3c, and the like classified into the category of the device A. For example, an average value of the DC voltages with respect to the difference in the time taken to decrease the temperature of the device A may be set as an appropriate value based on the information 3a, 3b, 3c, and the like, or a median value of the DC voltage with respect to the difference in the time taken to decrease the temperature of the device A may be set as an appropriate value. For example, a minimum value or a maximum value of the DC voltage with respect to the difference in the time taken to decrease the temperature of the device A may be set as an appropriate value based on the information 3a, 3b, 3c, and the like. In addition, the server 2 can calculate a specific value of the DC voltage based on the information 3a, 3b, 3c and the like as an appropriate value of the DC voltage with respect to the difference in the time taken to decrease the temperature of the device A.

Similarly, an appropriate value of the DC voltage with respect to the difference in the time taken to decrease the temperature of the device B is calculated based on the information 4a, 4b, 4c, and the like classified into the category of the device B. For example, the average value, the median value, the minimum value, or the maximum value of the DC voltage with respect to the difference in the time taken. to decrease the temperature of the device A may be set as an appropriate value based on the information 4a, 4b, 4c, and the like. In addition, the server 2 can calculate a specific value of the DC voltage based on the information 4a, 4b, 4c and the like as an appropriate value of the DC voltage with respect to the difference in the time taken to decrease the temperature of the device B.

The server 2 calculates an appropriate value of the DC voltage with respect to the difference in the time taken to decrease the temperature collected from different etching devices, and feedbacks the information on the appropriate value of the DC voltage with respect to the calculated difference in the time taken to decrease the temperature to the controllers 1a to 1c and 2a to 2c. Therefore, the controllers 1a to 1c and 2a to 2c can control the DC voltage applied to the edge ring 30 using the appropriate value of the DC voltage corresponding to the consumption amount of the edge ring 30 obtained from the information of other etching devices.

Accordingly, the server 2 can collect the information on the DC voltage with respect to the difference in the time taken to decrease the temperature measured using a larger number of plasma etching devices than those included in the same category. Thus, is possible to calculate the appropriate value of the DC voltage with respect to the difference in the time taken to decrease the temperature without variation based on the collected information on the DC voltage with respect to the difference in the time taken to decrease the temperature. Hence, it is possible to accurately control the application of the appropriate value of the DC voltage to the edge ring 30 corresponding to the consumption amount of the edge ring 30. The server 2 may be implemented as a cloud computer.

As described above, in accordance with the present embodiment, the consumption amount of the edge ring 30 can be estimated based on the measurement result of the variation of time for temperature decrease of the edge ring 30 from the first temperature to the second temperature or the variation of speed of the temperature decrease of the edge ring 30 from the first temperature to the second temperature. Further, at least one of the occurrence of tilting and the variation in the etching rate can be suppressed by applying an appropriate DC voltage to the edge ring 30 corresponding to the measurement result or the estimated degree of consumption of the edge ring 30. Accordingly, the replacement timing determined by the consumption amount of the edge ring 30 can be delayed. As a result, the productivity of the plasma etching device can be improved.

The plasma etching method and the plasma etching device according to the embodiments of the present disclosure are considered to be illustrative in all respects and not restrictive. The above-described embodiments can be embodied in various forms. Further, the above-described embodiments may be omitted, remounted, or changed in various forms without departing from the scope of the appended claims and the gist thereof. The above-described embodiments may include other configurations without contradicting each other and may be combined without contradicting each other.

The plasma etching device of the present disclosure can be applied to any type of apparatus using capacitively coupled plasma (CCP), inductively coupled plasma (ICP), a radial line slot antenna (RLSA), electron cyclotron resonance plasma (ECR), and helicon wave plasma (HWP).

In this specification, the wafer W has been described as an example of the target object. However, the target object is not limited thereto, and may be various substrates used for use in a fiat panel display (FPD), a printed circuit board, or the like.

This application claims priority to Japanese Patent Application No. 2018-127811, filed on Jul. 4, 2018, the entire contents of which are incorporated herein by reference.

### DESCRIPTION OF REFERENCE NUMERALS

1: Plasma etching device

10: Processing container

11: Substrate support

18: Gas exhaust unit

21: First RF power supply

22: Second RF power supply

24: Gas shower head

25: Electrostatic chuck

25a: Attraction electrode

25b: Dielectric layer

25c: Base

28: Variable DC power supply

29: Electrode

30: Edge ring

31: Coolant space

35: Heat transfer gas supply unit

40: Processing gas supply unit

43: Controller

51: Radiation thermometer

52, 62: Heater

29a, 52a, 56, 62a: insulator

1. A plasma etching method for etching a target object by plasma in a state where a pressure in a processing container having a consumable member is maintained at a constant level, comprising:
measuring variation of time for temperature decrease of the consumable member from a first temperature to a second temperature lower than the first temperature or variation of speed of the temperature decrease of the consumable member from the first temperature to the second temperature; and
estimating a degree of consumption of the consumable member from the variation of time or the variation of speed based on information on correlation between the variation of time or the variation of speed and the degree of consumption of the consumable member.

2. The plasma etching method of claim 1, further comprising:
controlling a DC voltage applied to the consumable member based on the estimated degree of consumption of the consumable member.

3. The plasma etching method of claim 1, wherein a driving amount of the consumable member is controlled based on the estimated degree of consumption of the consumable member.

4. The plasma etching method of claim 1, wherein the consumable member is at least one of an edge ring and an upper electrode.

5. The plasma etching method of claim 4, wherein the edge ring is divided into an inner peripheral edge ring, a central edge ring and an outer peripheral edge ring, and
a driving amount of at least one of the inner peripheral edge ring, the central edge ring and the outer peripheral edge ring is adjusted.

6. The plasma etching method of claim 1, wherein a pressure in the processing container is maintained at a constant level while supplying a gas at a constant flow rate into the processing container.

7. A plasma etching device comprising:
a processing container having a consumable member;
a gas supply unit configured to supply a gas;
a measuring unit configured to measure a temperature of the consumable member;
a heating unit configured to heat the consumable member; and
a controller,
wherein the controller maintains a pressure in the processing container at a constant level while supplying a gas into the processing container, measures variation of time for temperature decrease of the consumable member from a first temperature to a second temperature lower than the first temperature or variation of speed of the temperature decrease of the consumable member from the first temperature to the second temperature, and estimates a degree of consumption of the consumable member from the variation of time or the variation of speed based on information on correlation between the variation of time or the variation of speed and the degree of consumption of the consumable member.

8. The plasma etching method of claim 2, wherein a driving amount of the consumable member is controlled based on the estimated degree of consumption of the consumable member.

9. The plasma etching method of claim 2, wherein the consumable member is at least one of an edge ring and an upper electrode.

10. The plasma etching method of claim 2, wherein a pressure in the processing container is maintained at a constant level while supplying a gas at a constant flow rate into the processing container.
